(19) United States
(12) Patent Application Publication
(10) Pub. No.: US 2007/0298583 A1
(43) Pub. Date: Dec. 27, 2007

(54) METHOD FOR FORMING A SHALLOW TRENCH ISOLATION REGION

(75) Inventors: Chia-Wei Wu, Taichung (TW); Chen-Wei Liao, Nantou (TW); Jung-Yu Hsieh, Hsinchu (TW); Ling-Wuu Yang, Hsinchu (TW); Chin-Ta Su, Yunlin (TW); Chi-Tung Huang, Hsinchu (TW)

Correspondence Address: BAKER & MCKENZIE LLP;PATENT DEPARTMENT, 2001 ROSS AVENUE, SUITE 2300, DALLAS, TX, 75201, US

(73) Assignee: MACRONIX INTERNATIONAL CO., LTD., Hsinchu (TW)

(21) Appl. No.: 11/426,650

(22) Filed: Jun. 27, 2006

(51) Int. Cl. H01L 21/76

(52) U.S. Cl. 438/424

(57) ABSTRACT

A method for forming a shallow trench isolation region (STI) is disclosed. The method comprises the steps of sequentially forming a pad oxide layer and a nitride silicon layer over a provided substrate. Next, the pad oxide layer, the nitride silicon layer, and the substrate are partially etched to form a trench. An oxide liner and a nitride liner are then formed in the trench. Subsequently, a two-stage high-density plasma chemical vapor deposition process is performed to form a shallow trench isolation region.

### BACKGROUND OF THE INVENTION

1. Field of the Invention

The present invention relates to a method of manufacturing semiconductor devices and, in particular, certain embodiments of the invention relate to a method for forming a shallow trench isolation (STI) region in a semiconductor substrate.

2. Description of the Related Art

In the manufacturing of integrated circuits, to ensure that the devices on the circuit operate without interfering with each other, each device must be electrically isolated. However, as circuits and devices become smaller, the device isolation regions are also required to become smaller in size. This leads to new complexities and challenges in the art of isolating semiconductor devices.

Conventionally in the manufacture of 350 nm or larger scale integrated circuits, a process known as local oxidation of silicon (LOCOS) is used to form isolation regions between the devices. However the field oxide layer produced by the LOCOS method often builds up internal stress, which can create a so-called bird's beak phenomenon that can result in current leakage between devices. Further, isolation regions manufactured by a conventional LOCOS method suffer uneven surfaces. The shallow trench isolation (STI) method was developed to address the limitations of the LOCOS method, and to manufacture highly integrated circuits that are 250 nm or smaller.

FIGS. 1A through 1D describe the steps of the conventional STI method. First, as shown in FIG. 1A, a pad oxide layer 102 is formed over a substrate 100 using a thermal oxidation method. Next, a silicon nitride layer 104 is formed over the pad oxide layer 102 using a low-pressure chemical vapor deposition method.

Next, in FIG. 1B, the silicon nitride layer 104, the pad oxide layer 102, and the substrate 100 are partially etched. As a result, a patterned silicon nitride layer, a patterned pad oxide layer, and a trench 106, are formed.

In FIG. 1C, a first oxide liner 108 is formed over the substrate surface of the trench 106. Thereafter, suitable dielectric is deposited into the trench 106 and formed a dielectric layer 110. Using the silicon nitride layer 104 as a polishing stop layer, Chemical Mechanical Polishing (CMP) is carried out to remove excess dielectrics.

Next, the silicon nitride layer 104 and the pad oxide layer 102 are removed to form a shallow trench isolation 116, as shown in FIG. 1D.

Although STI can increase device integrity, it is not without flaws. First, incompatibilities between the oxide liner 108 and the substrate 100 create a dislocation problem. This problem further impedes reactants (such as oxygen) from associating with the gate oxide, which subsequently creates an oxide thinning issue near the STI region.

U.S. Pat. No. 6,180,493 describes a method for forming an STI region that attempts to resolve the above-mentioned problem. The method essentially creates a plurality of insulation layers inside the trench of the STI region in an oxygen-filled atmosphere. However, in addition to requiring the formation of a plurality of insulation layers, a buffer layer, and an oxide liner, this method needs to be carefully timed to control the thickness of these layers. Thus, this method is too complicated, which can increase costs, and time consuming, which reduces throughput.

U.S. Pat. No. 6,200,881 discloses another method for forming an STI region. Although the method addresses the dislocation problem and the oxide thinning issue, it still involves intricate and challenging procedures that are not cost effective.

Accordingly, there is a need for an improved method of forming a shallow trench isolation region that is not only cost effective, but also resolves the problems of dislocation and oxide thinning.

### SUMMARY OF THE INVENTION

Certain embodiments of the present invention are directed to a method for forming a shallow trench isolation region capable of solving both the leakage problem induced by dislocation and the issue of oxide thinning.

Certain embodiments of the present invention are further directed to a method for forming an STI region, where, during a two-stage high-density plasma chemical vapor deposition process (HDP CVD), dielectric deposition in the trench is first carried out in-situ. Once the oxide layer, which previously was deposited in the trench, is exposed, the rest of the trench is filled with additional dielectric. This simple and cost effective method resolves the problems in the prior art.

Certain embodiments of the present invention are further directed to a method for forming an STI region, where during the two-stage HDP CVD, two chemical vapor deposition processes are performed sequentially. The in-situ two-stage HDP CVD not only reduces the chance of contamination by impurities, it also simplifies manufacturing procedures and thus increases production capacity.

Certain embodiments of the present invention are further directed to a method for forming an STI region, where strict monitoring of the process window is not necessary during the second stage of the chemical vapor deposition process. This results in the benefit of increasing production capacity.

Certain embodiments of the present invention are further directed to a method for forming an STI region. First, a substrate is provided. Next, a pad oxide layer and a silicon nitride layer are sequentially formed over the substrate. Then, the silicon nitride layer, the pad oxide layer, and the substrate are partially etched to form a trench. Next, an oxide liner and a nitride liner are formed in the trench, undergoing first and second stages of HDP CVD. The silicon nitride layer and the pad oxide layer are then removed, creating a shallow trench isolation region. During the two-stage HDP CVD, dielectrics are first deposited on the nitride liner. Then, the top part of the oxide liner is exposed and dielectrics are used to fill the remaining trench, forming a dielectric layer. Finally, the silicon nitride layer and the pad oxide layer are removed, forming the shallow trench isolation region.

Certain embodiments of the present invention are further directed to a method for forming an STI region. First, a substrate is provided. Next, a pad oxide layer and a silicon nitride layer are sequentially formed over the substrate. Then, the silicon nitride layer, the pad oxide layer, and the substrate are partially etched to form a trench. Next, an oxide liner and a nitride liner are formed in the trench, undergoing a first stage of the chemical vapor deposition process, followed by a second stage of HDP CVD. The silicon nitride layer and the pad oxide are then removed, and a shallow trench isolation region is formed. Specifically, dielectrics are deposited on the nitride liner during the first stage of the chemical vapor deposition process. Thereafter, the top part of the oxide liner is exposed during the second stage of HDP CVD. Dielectrics are then used to fill the remaining shallow trench, forming a dielectric layer. The silicon nitride layer and the pad oxide layer are subsequently removed, forming the final shallow trench isolation region.

Certain embodiments of the present invention are further directed to a method for forming an STI region. First, a substrate is provided. Next, a pad oxide layer and a silicon nitride layer are sequentially formed over the substrate. Then, the silicon nitride layer, the pad oxide layer, and the substrate are partially etched to form a trench. Next, an oxide liner and a nitride liner are formed in sequence inside the trench, and dielectrics are deposited over the nitride liner. Hydrofluoric acid (HF) is used for etching the top part of the dielectrics, and phosphoric acid (H3PO4)is then used for etching the nitride liner, and the top part of the oxide liner is therefore exposed. Thereafter, dielectrics are used to fill the rest of the trench, creating a dielectric layer. Finally, the silicon nitride layer and the pad oxide layer are removed, forming the shallow trench isolation region.

### BRIEF DESCRIPTION OF THE DRAWINGS

FIG. 1A is a cross-sectional view showing the substrate 100, pad oxide layer 102, and silicon nitride layer 104 used to form an STI region.

FIG. 1B is a cross-sectional view showing a trench 106 formed in FIG. 1A.

FIG. 1C is a cross-sectional view showing a first oxide liner 108 and a dielectric layer 110 formed in trench 106.

FIG. 1D is a cross-sectional view showing a shallow trench isolation region.

FIG. 2A illustrates certain embodiments of the present invention including substrate 200, pad oxide layer 202, and silicon nitride layer 204.

FIG. 2B is a cross-sectional view showing a trench 206 formed in FIG. 2A according to certain embodiments of the present invention.

FIG. 2C is a cross-sectional view showing a first oxide liner 208 and a nitride liner 210 formed in trench 206 according to certain embodiments of the present invention.

FIG. 2D is a cross-sectional view showing the progression of the first stage chemical vapor deposition process according to certain embodiments of the present invention.

FIG. 2E is a cross-sectional view showing the progression of the second stage chemical vapor deposition process according to certain embodiments of the present invention.

FIG. 2F is a cross-sectional view showing a shallow trench isolation region according to certain embodiments of the present invention.

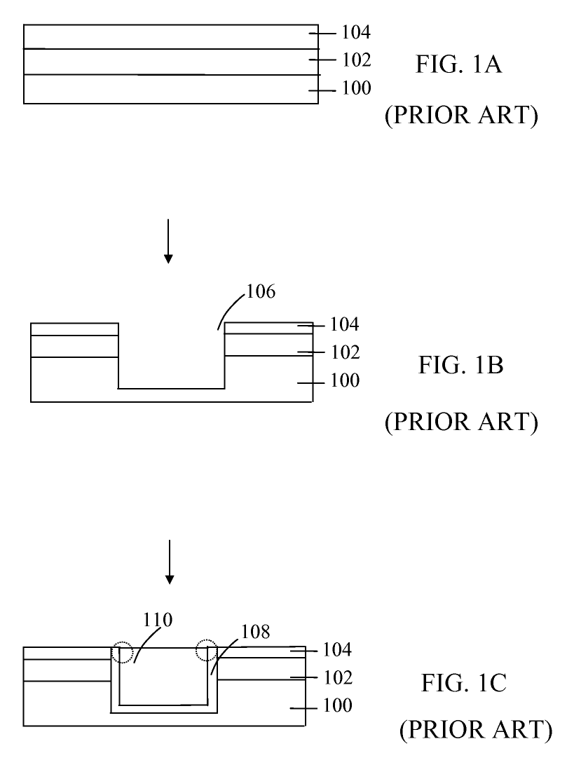

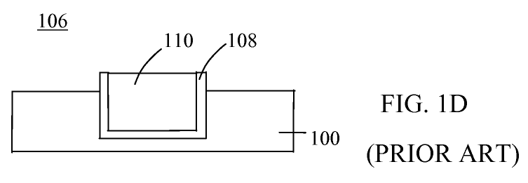

### DETAILED DESCRIPTION OF PREFERRED EMBODIMENTS

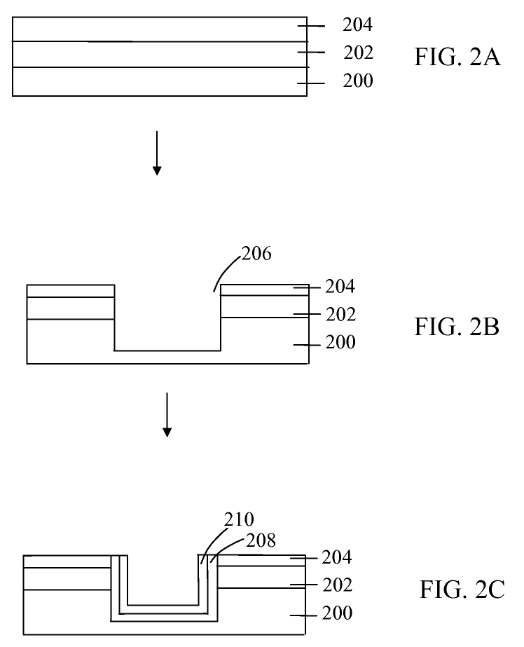

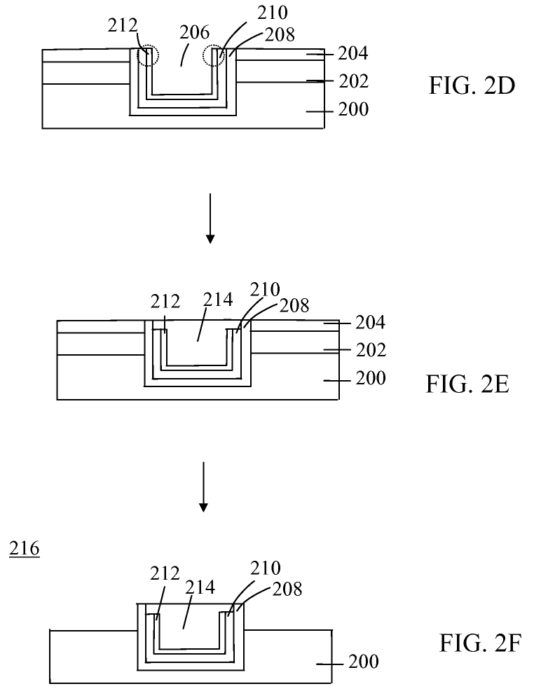

FIGS. 2A through 2F are schematic, cross-sectional views displaying the manufacturing steps of forming shallow trench isolation regions in a substrate according to certain embodiments of the present invention.

Referring to FIG. 2A, a substrate 200 is provided. Using a thermal oxidation method, a pad oxide layer 202 is formed over the substrate to protect the substrate surface from damage. Next, a silicon nitride layer 204 is formed over the pad oxide layer 202 using either a chemical vapor deposition method or other appropriate methods. Due to its resistance against vapor and oxygen penetration, the silicon nitride layer 204 can prevent the active region beneath it from oxidation. The difference in etch rate of the silicon nitride and other materials, such as silicon dioxide, is called etch selectivity. Etch selectivity allows the silicon nitride layer 204 to serve as a hard mask and an etch stop layer.

After the silicon nitride layer 204 is formed, it is patterned to define the position of a trench 206 (See FIG. 2B). The silicon nitride layer 204 is patterned using techniques common in the art such as photolithography and etching. Particularly, a photo-resist layer (not shown) is first formed over the silicon nitride layer 204. The silicon nitride layer is then etched and the photoresist layer is removed, completing the patterning procedures. Next, using the silicon nitride layer 204 as a hard mask and an etch stop layer, and taking advantage of the differences in materials between the pad oxide layer, the substrate, and the silicon nitride layer, the pad oxide layer and the substrate are etched using an anisotropic etching method such as dry etching to form the trench 206 (as seen in FIG. 2B).

Utilizing thermal oxidation or chemical vapor deposition, for example PECVD or HDP CVD, a first oxide liner 208 is formed inside the trench 206 to mitigate the damage that substrate 200 suffers from etching. Due to lattice incompatibilities between the first oxide liner 208 and the substrate 200, dislocation will occur. Thus, certain embodiments of the present invention utilize chemical vapor deposition such as PECVD or HDP CVD to deposit nitride over first oxide liner 208, forming a nitride liner 210 over the first oxide liner 208. According to one embodiment of the present invention, silicon nitride can be used.

Next, a two-stage high-density plasma chemical vapor deposition (HDP CVD) is conducted. The term “two-stage high density plasma chemical vapor deposition” means that the chemical deposition process is carried out twice with high-density plasma equipment. The two chemical deposition processes can be conducted sequentially; or other conventional processes, such as cleaning, etching, or deposition, can be performed in between the two processes.

Another preferred embodiment of the present invention involves conducting two chemical deposition processes, in sequence, with the same high-density plasma equipment. Carrying out two chemical vapor deposition processes in-situ can reduce device contamination by impurities, thus increase throughput. Moreover, the in-situ method also simplifies manufacturing process and boosts production capacity. The high-density plasma equipment commonly found in the manufacturing of semiconductors can be used.

To clarify this embodiment, the first and second stages of the chemical vapor deposition process are illustrated in FIG. 2D and FIG. 2E. Referring to FIG. 2D, the first stage chemical vapor deposition process is described. First, using tetra-ethyl-ortho-silicate (TEOS) as a gaseous reactant, a second oxide liner 212 is formed. In this embodiment, the second oxide liner 212 is deposited along the profile of the nitride liner 210 in the trench 206, i.e. a conformal deposition known in the prior art. To protect the nitride liner 210, high-density plasma bias is reduced during the dielectrics deposition step in order to avoid ion bombardment of the second oxide liner 212. The second oxide liner 212 can shield the nitride liner 210 from damage. The degree of bias can be adjusted to ensure that the nitride liner 210 is not damaged by ion bombardment.

Subsequently, the second stage of the chemical vapor deposition process is performed with the same high-density plasma equipment. During this step, the etching to deposition ratio (E/D) is monitored and tuned. While the top part of the second oxide liner 212 and the nitride liner 210 (dotted area in FIG. 2D) undergo ion bombardment, the top part of the first oxide liner 208 is no longer covered by the second oxide liner 212 and the nitride liner 210. A dielectric layer 214 is then formed by filling the rest of the trench 206 with dielectrics, as illustrated in FIG. 2E. The E/D ratio can be calculated by one skilled in the art from the following formula:

$$\frac{E}{D} = \frac{UBUC - BC}{UBUC}$$

Here, “UBUC” is the thickness of the second oxide liner 212 during high-density plasma chemical vapor deposition close bias. “BC” is the thickness of the second oxide liner 212 during high-density plasma chemical vapor deposition open bias. “UBUC−BC” is the reduction in thickness of second oxide liner 212 from ion bombardment. Thus, the above formula yields an etching to deposition ratio. This formula is only one of many methods for calculating E/D ratio. People skilled in the relevant art can also determine the ratio by employing different methods such as monitoring or tuning the second stage chemical vapor deposition time.

According to certain embodiments of the present invention, the range of the E/D ratio is set to between 0.05 and 0.13 (approximately 0.09±0.04). Because the second stage chemical vapor deposition process requires exposure of the top part of the first oxide liner 208 so that the substrate 200 would not be harmed, the E/D ratio can be adjusted easily by one skilled in the art. Thus, strict monitoring and tuning of the second stage chemical vapor deposition process is not necessary, allowing increase in production capacity. It should be noted that silicon dioxide and other dielectrics are all suitable second oxide liner materials.

According to certain embodiments of the present invention, the first and the second stage chemical vapor deposition process can be conducted ex-situ. Therefore, cleaning, etching, or deposition can be performed in between the two CVD processes. Referring to FIG. 2D and FIG. 2E, first a second oxide liner 212 is formed using TEOS as gas reactant in a chemical vapor deposition operation. The second oxide liner 212 is deposited along the profile of the nitride liner 210 in the trench 206 as shown in FIG. 2D, i.e. a conformal deposition known in the prior art. To avoid damage to the nitride liner 210 from ion bombardment during the formation of the second oxide liner 212, the process is conducted in high-density plasma chemical vapor deposition close bias.

Next, the top part of the second oxide liner 212 and the nitride liner 210 (dotted region in FIG. 2D are removed in an etching operation. For example, the structure shown in FIG. 2D is first dipped in a dilute hydrofluoric acid to remove part of the second oxide liner 212, and then dipped in a phosphoric acid to remove any exposed nitride liner 210. Consequently, the top part of the first oxide liner 208 is no longer covered by the second oxide liner 212 and the nitride liner 210. According to certain embodiments of the present invention, the dilute hydrofluoric acid dip is carried out at room temperature for more than 4 minutes, and the phosphoric acid dip is carried out at 160° C. for about 1 minute. The dilute hydrofluoric acid dip can be prepared by diluting hydrofluoric acid (49% by weight) with deionized water by a volume ratio of 1:50. The volume concentration of the phosphoric acid can be about 86%. Finally, the dielectric layer 214 is formed by filling the rest of the trench 206 with dielectrics deposits.

Referring to FIG. 2F, the silicon nitride layer 204 and the pad oxide layer 202 are removed. Thus, the first oxide liner 208, the nitride liner 210, the second oxide liner 212, and the dielectric layer 214, together form a shallow trench isolation region 216.

In another embodiment, the second oxide liner 212 is deposited over part of the nitride liner 210 during the first stage chemical vapor deposition process, such that the height of the second oxide liner 212 is lower than the height of the nitride liner 210. Part of the nitride liner 210 is therefore covered while the top part of the nitride liner 210 is exposed. The top of the second oxide liner 212 no longer needs to be removed in the subsequent process. Next, the nitride liner 212 is removed and the rest of the trench 206 is filled in using high-density plasma equipment by controlling the E/D ratio or other process conditions mentioned above. Alternatively, the nitride liner 212 can be removed in a phosphoric acid dip, and then the trench 206 can be filled in a chemical vapor deposition equipment. The process conditions, such as volume concentration of phosphoric acid, temperature and process time have been explained in detail above. It should be noted that any dielectric material with high dielectric constant can replace the material of the second oxide liner, such as spin-on glass (SOG).

In summary, because a nitride liner 210 is formed above the first oxide liner 208, lattice incompatibilities between the first oxide liner 208 and the substrate 200 are mitigated. Next, during the first stage chemical vapor deposition process, a second oxide liner 212 is formed to protect the nitride liner 210. In the second stage chemical vapor deposition process, the first oxide liner 208 is exposed by monitoring and tuning the E/D ratio. Subsequently, the trench 206 is filled with dielectric, thereby allowing the first oxide liner 208, the nitride liner 210, the second oxide liner 212, and the dielectric layer 214 together to form a shallow trench isolation region 216. Alternatively, an etching operation can substitute for ion bombardment during the second stage chemical vapor deposition process in high-density plasma equipment.

It will be apparent to those skilled in the art that various modifications and variations can be made in the disclosed process without departing from the scope or spirit of the present invention. Other embodiments of the invention will be apparent to those skilled in the art from consideration of the specification and practice of the invention disclosed herein. It is intended that the specification and examples be considered as exemplary only, with the true scope of the invention being indicated by the following claims and their equivalents.

We claim:

1. A method for forming a shallow trench isolation region, comprising:
providing a substrate;
forming a pad oxide layer over the substrate;
forming a silicon nitride layer over the pad oxide layer;
patterning the silicon nitride layer, the pad oxide layer, and the substrate to form a trench;
forming an oxide liner over the trench;
forming a nitride liner over the oxide liner; and
performing an in-situ two-stage high-density plasma chemical vapor deposition process, wherein the two-stage high-density plasma chemical vapor deposition process comprises:
depositing a first dielectric over the nitride liner in a first stage chemical vapor deposition process,
removing a top part of the nitride liner and simultaneously depositing a second dielectric to fill the trench in a second stage chemical vapor deposition process.

2. The method according to claim 1, wherein the step of removing a top part of the nitride liner is performed by ion bombardment.

3. The method according to claim 2, wherein the etching to deposition ratio of the second stage chemical vapor deposition process is between 0.05 to 0.13.

4. The method according to claim 2, further comprising removing a top part of the first dielectric in con junction with the step of removing the top part of the nitride liner.

5. The method according to claim 1, wherein the first dielectric is deposited over part of the nitride liner in the first stage chemical vapor deposition process, and a height of the first dielectric is lower than a height of the nitride liner.

6. A method for forming a semiconductor device, comprising:
providing a substrate:
forming a pad oxide layer over the substrate;
forming a silicon nitride layer over the pad oxide layer;
patterning the silicon nitride layer, the pad oxide layer, and the substrate to form a trench;
forming a nitride liner within the trench;
depositing a first dielectric over a nitride liner;
removing a top part of the nitride liner; and
depositing a second dielectric to fill the trench to form a shallow trench isolation region.

7. The method according to claim 6, further comprising removing a top part of the first dielectric in conjunction with the step of removing the top part of the nitride liner.

8. The method according to claim 6 wherein the step of removing the top part of the nitride liner is performed by ion bombardment.

9. The method according to claim 8, wherein the etching to deposition ratio of the step of depositing the second dielectric is between 0.05 to 0.13.

10. The method according to claim 6, wherein the first dielectric is deposited over part of the nitride liner, and a height of the first dielectric is lower than a height of the nitride liner.

11. The method according to claim 6, wherein the depositing of the first dielectric and depositing of the second dielectric are performed using the same high-density plasma chemical vapor deposition equipment.

12. The method according to claim 6, wherein the step of removing the top part of the nitride liner is performed using phosphoric acid.

13. The method according to claim 6, further comprising removing a top part of the first dielectric.

14. The method according to claim 13, wherein the step of removing the top part of the first dielectric is performed using hydrofluoric acid.
